(19) United States
(12) Patent Application Publication
(10) Pub. No.: US 2021/0104280 A1
(43) Pub. Date: Apr. 8, 2021

(54) METHOD OF REDUCING NEIGHBORING WORD-LINE INTERFERENCE

(71) Applicant: SanDisk Technologies LLC, Addison, TX (US)

(72) Inventors: Sung-Chul Lee, San Jose, CA (US); Ching-Huang Lu, Fremont, CA (US); Henry Chin, Fremont, CA (US); Changyuan Chen, San Jose, CA (US)

(73) Assignee: SanDisk Technologies LLC, Addison, TX (US)

(21) Appl. No.: 16/593,393

(22) Filed: Oct. 4, 2019

(51) Int. Cl. G11C 16/16; G11C 16/34; G11C 16/04

(52) U.S. Cl. CPC G11C 16/16; G11C 16/0483; G11C 16/3445

(57) ABSTRACT

Method for performing an erase program operation. Various methods include: erasing a block of cells by: applying a program pulse to a block of memory elements in the three-dimensional memory that programs the block of memory elements to a level below an erase verify level, where the three-dimensional memory comprises memory elements stacked vertically; performing a verify step to verify voltage levels of a group of memory elements; determining that a memory element of the group is outside of a threshold window defined between the erase verify level and a compact erase threshold amount; and applying a second program pulse to the memory element. Where erasing the block of memory elements creates an erased block, where a width of the voltage distribution of the erased memory elements in the erased block is the same as or below a width of a voltage distribution associated with programmed memory elements.

### BACKGROUND

Non-volatile memory systems retain stored information without requiring an external power source. One type of non-volatile memory that is used ubiquitously throughout various computing devices and in stand-alone memory devices is flash memory. For example, flash memory can be found in a laptop, a digital audio player, a digital camera, a smart phone, a video game, a scientific instrument, an industrial robot, medical electronics, a solid state drive, and a USB drive.

Flash memory can be implemented as a three-dimensional memory array, where memory cells are vertically stacked. Additionally, flash memory continues to become denser. As flash memory becomes more dense, word-lines are disposed closer to each other and issues caused by neighboring word-line interference increases. During operation of the flash memory, neighboring word-line interference can impact data retention, power, and operations such as program and read.

### SUMMARY

Various embodiments include a method for reducing neighboring word-line interference in a three-dimensional memory, including: erasing a block of memory elements by: applying a program pulse to a block of memory elements in the three-dimensional memory that programs the block of memory elements to a level below and erase verify level, wherein the three-dimensional memory comprises memory elements stacked vertically; performing a verify step to verify voltage levels of a group of memory elements; determining that a memory element of the group of memory elements is outside a threshold window defined between the erase verify level and a compact erase threshold amount; and applying a second program pulse to the memory element.

Other embodiments include a memory controller, including: a first terminal configured to couple to a three-dimensional memory, wherein the three-dimensional memory comprises memory elements stacked vertically, the memory controller configured to use an erase program operation that erases the memory block to a compact-erased state, wherein when the controller applies the erase program operation, the controller is configured to: apply a program pulse to a block of memory elements in the three-dimensional memory that programs the block of memory elements to a level below and erase verify level; perform a verify step to verify voltage levels of a group of memory elements; determine that a memory element of the group of memory elements is outside a threshold window defined between the erase verify level and a compact erase threshold amount; and apply a second program pulse to the memory element.

Additional embodiments include a non-volatile storage system, configured to perform an erase program operation, including: a three-dimensional memory including memory elements stacked vertically; and a controller coupled to the three-dimensional memory, where the controller is configured to erase a block of memory elements by using the erase program operation, where when the controller applies the erase program operation, the controller is configured to: apply a program pulse to the block of memory elements in the three-dimensional memory that programs the block of memory elements to a level below an erase verify level, perform a verify step to verify voltage levels of a group of memory elements; determine that a memory element of the group of memory elements is outside of a threshold window defined between the erase verify level and a compact erase threshold amount; and apply a second program pulse to the memory element.

### BRIEF DESCRIPTION OF THE DRAWINGS

For a detailed description of example embodiments, reference will now be made to the accompanying drawings in which:

FIG. 1 illustrates a block diagram of an example non-volatile memory system, in accordance with some embodiments.

FIG. 2a illustrates an example architecture of an example three-dimensional memory, in the form of an equivalent circuit of a portion of such memory, in accordance with some embodiments.

FIG. 2b illustrates a plan view of two memory planes, in accordance with some embodiments.

FIG. 3 illustrates a perspective view of a memory device 300 of an example three-dimensional memory, in accordance with some embodiments.

FIG. 4 illustrates plots of voltage distributions, in accordance with some embodiments.

FIG. 5a illustrates plots illustrating a compaction process, in accordance with some embodiments.

FIG. 5b illustrates plots of voltage distributions, in accordance with some embodiments.

FIG. 6 illustrates plots of voltage distributions, in accordance with some embodiments.

FIG. 7 illustrates plots of voltage distributions, in accordance with some embodiments.

FIG. 8 illustrates plots of voltage distributions, in accordance with some embodiments.

FIG. 9 illustrates a method diagram, in accordance with some embodiments.

FIG. 10 illustrates a block diagram of an example memory system, in accordance with some embodiments.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be an example of that embodiment, and not intended to imply that the scope of the disclosure, including the claims, is limited to that embodiment.

Various terms are used to refer to particular system components. Different companies may refer to a component by different names—this document does not intend to distinguish between components that differ in name but not function. In the following discussion and in the claims, the terms “including” and “comprising” are used in an open-ended fashion, and thus should be interpreted to mean “including, but not limited to . . . ” Also, the term “couple” or “couples” is intended to mean either an indirect or direct connection. Thus, if a first device couples to a second device, that connection may be through a direct connection or through an indirect connection via other devices and connections. References to a controller shall mean individual circuit components, an application-specific integrated circuit (ASIC), a microcontroller with controlling software, a digital signal processor (DSP), a processor with controlling software, a field programmable gate array (FPGA), or combinations thereof.

At least some of the example embodiments are directed to a method for reducing neighboring word-line interference in a three-dimensional memory, including: erasing a block of cells by applying a program pulse that is part of an erase program operation. The program pulse effectively programs the memory cells to a compact-erased state to create erased memory cells.

As the density of flash memory increases and memory cells decreased in size, issues related to neighboring word-line interference can increase. For reasons described herein, by using a program operation to transition the memory cells to an erased state (referred to herein as a compact-erased state), a voltage distribution of the erased memory cells is compacted. The compacted voltage distribution helps reduce neighboring word-line interference during subsequent program operations. Various characteristics of a compacted voltage distribution of compact-erased memory cells are described herein.

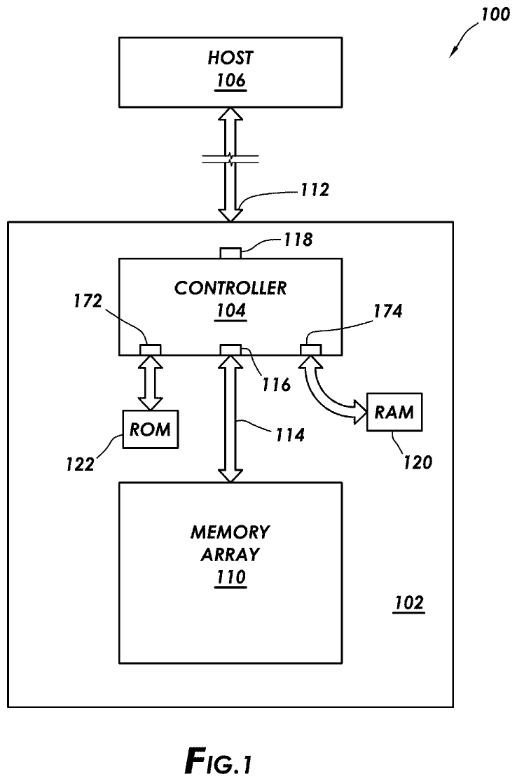

FIG. 1 illustrates a block diagram of an example system architecture 100 including non-volatile memory “NVM” array 110 (hereinafter “memory 110”). In particular, the example system architecture 100 includes storage system 102 that further includes a controller 104 communicatively coupled to a host 106 by a bus 112. The bus 112 implements any known or after developed communication protocol that enables the storage system 102 and the host 106 to communicate. Some non-limiting examples of a communication protocol include Secure Digital (SD) protocol, Memory Stick (MS) protocol, Universal Serial Bus (USB) protocol, or Advanced Microcontroller Bus Architecture (AMBA).

The controller 104 has at least a first port 116 coupled to the memory 110 by way of a communication interface 114. The memory 110 is disposed within the storage system 102. The controller 104 couples the host 106 by way of a second port 118 and the bus 112. The first and second ports 116 and 118 of the controller can include one or several channels that couple the memory 110 or the host 106, respectively.

Additionally, the controller 104 may be coupled to a random access memory (RAM) 120 and a read only memory (ROM) 122. The RAM 120 and ROM 122 are respectively coupled to the controller 104 by a RAM port 174 and a ROM port 172. Although the RAM 120 and the ROM 122 are shown as separate modules within the storage system 102, the illustrated architecture is not meant to be limiting. For example, the RAM 120 and the ROM 122 can be located within the controller 104. In other cases, portions of the RAM 120 or ROM 122, respectively, can be located outside the controller 104. In other embodiments, the controller 104, the RAM 120, and the ROM 122 are located on separate semiconductor die.

The memory 110 of the storage system 102 includes several memory die. The manner in which the memory 110 is defined in FIG. 1 is not meant to be limiting. In some embodiments, the memory 110 defines a physical set of memory die. In other embodiments, the memory 110 defines a logical set of memory die, where the memory 110 includes memory die from several physically different sets of memory die. A memory die includes non-volatile memory cells that retain data even when there is a disruption in the power supply. Thus, the storage system 102 can be easily transported and the storage system 102 can be used in memory cards and other memory devices that are not always connected to a power supply.

In various embodiments, the memory cells in the memory die are solid-state memory cells (e.g., flash), one-time programmable, few-time programmable, or many time programmable. Additionally, the memory cells in the memory die 110 can include single-level cells (SLC), multiple-level cells (MLC), or triple-level cells (TLC). In some embodiments, the memory cells are fabricated in a planar manner (e.g., 2D NAND (NOT-AND) flash) or in a stacked or layered manner (e.g., 3D NAND flash). Furthermore, the memory cells can use charge-trapping technology to store data.

Still referring to FIG. 1, the controller 104 and the memory 110 are communicatively coupled by an interface 114 implemented by several channels (e.g., physical connections) disposed between the controller 104 and the individual memory die 110-1-110-N. The depiction of a single interface 114 is not meant to be limiting as one or more interfaces can be used to communicatively couple the same components. The number of channels over which the interface 114 is established varies based on the capabilities of the controller 104. Additionally, a single channel can be configured to communicatively couple more than one memory die. Thus the first port 116 can couple one or several channels implementing the interface 114. The interface 114 implements any known or after developed communication protocol. In embodiments where the storage system 102 is flash memory, the interface 114 is a flash interface, such as Toggle Mode 200, 400, or 800, or Common Flash Memory Interface (CFI).

In various embodiments, the host 106 includes any device or system that utilizes the storage system 102—e.g., a computing device, a memory card, a flash drive. In some example embodiments, the storage system 102 is embedded within the host 106—e.g., a solid state disk (SSD) drive installed in a laptop computer. In additional embodiments, the system architecture 100 is embedded within the host 106 such that the host 106 and the storage system 102 including the controller 104 are formed on a single integrated circuit chip. In embodiments where the system architecture 100 is implemented within a memory card, the host 106 can include a built-in receptacle or adapters for one or more types of memory cards or flash drives (e.g., a universal serial bus (USB) port, or a memory card slot).

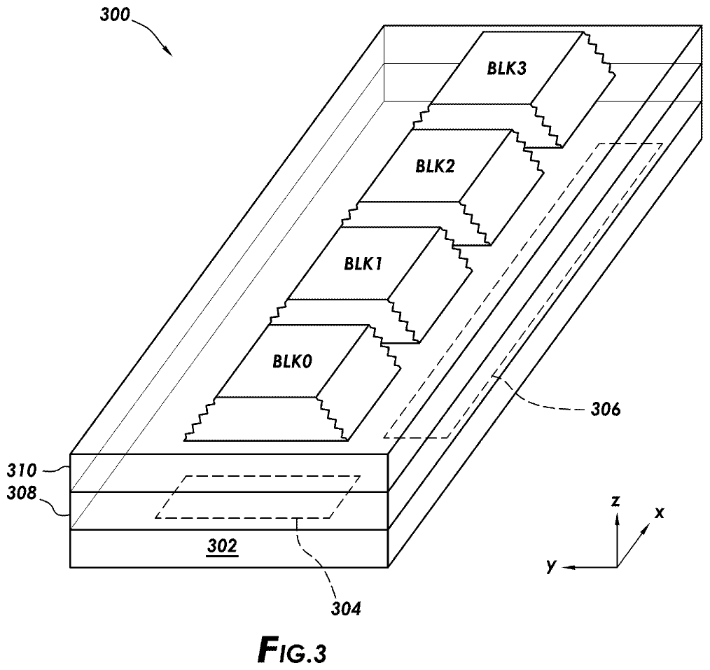

Although, the storage system 102 includes its own memory controller and drivers (e.g., controller 104)—as will be described further below in FIG. 3—the example described in FIG. 1 is not meant to be limiting. Other embodiments of the storage system 102 include memory-only units that are instead controlled by software executed by a controller on the host 106 (e.g., a processor of a computing device controls—including error handling of—the storage unit 102). Additionally, any method described herein as being performed by the controller 104 can also be performed by the controller of the host 106.

Still referring to FIG. 1, the host 106 includes its own controller (e.g., a processor) configured to execute instructions stored in the storage system 102 and further the host 106 accesses data stored in the storage system 102, referred to herein as “host data”. The host data includes data originating from and pertaining to applications executing on the host 106. In one example, the host 106 accesses host data stored in the storage system 102 by providing a logical address to the controller 104 which the controller 104 converts to a physical address. The controller 104 accesses the data or particular storage location associated with the physical address and facilitates transferring data between the storage system 102 and the host 106.

In embodiments where the storage system 102 includes flash memory, the controller 104 formats the flash memory to ensure the memory is operating properly, maps out bad flash memory cells, and allocates spare cells to be substituted for future failed cells or used to hold firmware to operate the flash memory controller (e.g., the controller 104). Furthermore, the controller 104 can implement an erase program operation as described herein or any other operation that compacts a distribution of erased memory cells. Thus, the controller 104 performs various memory management functions such as compaction (as described herein), wear leveling (e.g., distributing writes to extend the lifetime of the memory blocks), garbage collection (e.g., moving valid pages of data to a new block and erasing the previously used block), and error detection and correction (e.g., read error handling).

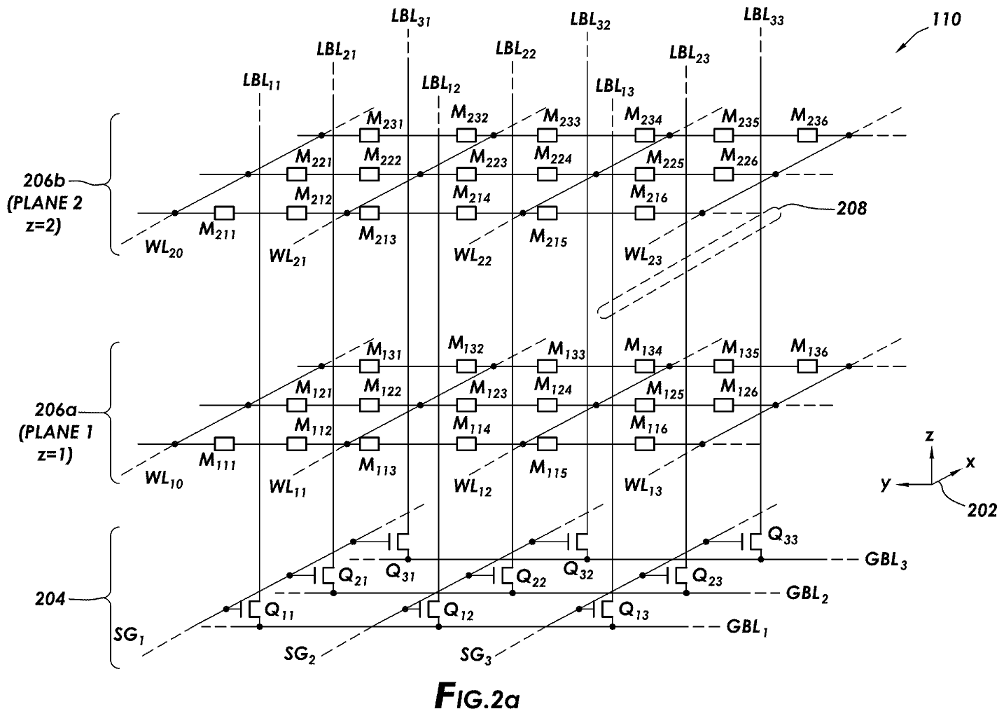

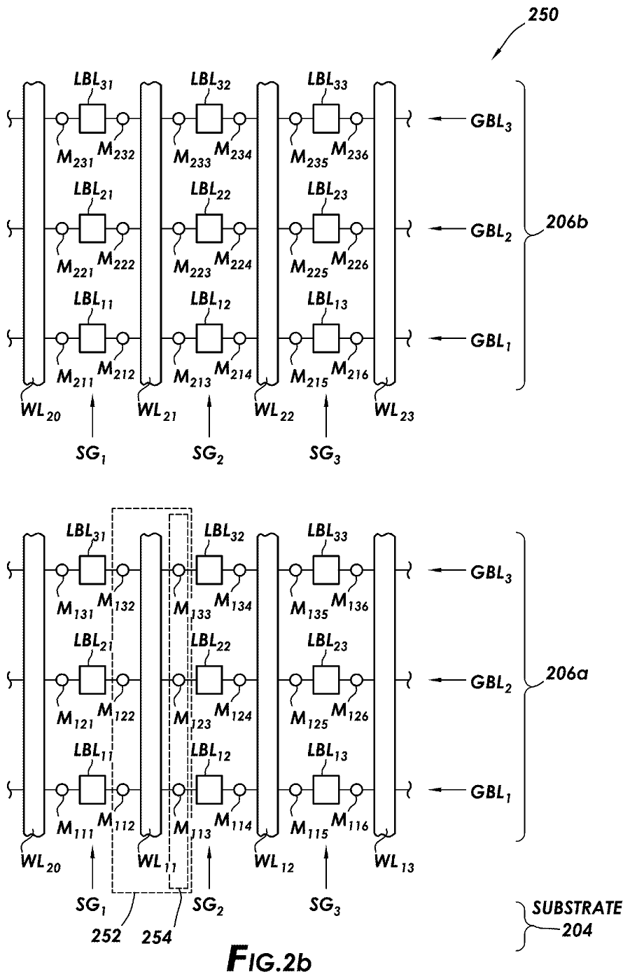

Additional details of the controller 104 and the memory 110 are described next in FIGS. 2 and 3. Specifically, FIG. 2 illustrates an architecture of a three-dimensional memory in schematic form of an equivalent circuit of a portion of memory 110. A coordinate system 202 is used for reference, where the directions for vectors x, y, and z are illustrated. Each of the vectors x, y, and z are orthogonal with the other two.

The three-dimensional memory includes a substrate layer 204, and one or more planes of memory 206a and 206b. The substrate layer 204 may define one or more circuits for selectively connecting internal memory elements with external data circuits. While each of the planes of memory 206 includes several memory storage elements M_{zxy}.

In particular, the substrate layer 204 includes a two-dimensional array of selecting devices or switches Q_{xy}, where x defines a relative position of the device in the x-direction and y defines a relative position of the device in the y-direction. In one embodiment, the individual devices Q_{xy} are select gates or select transistors.

Global bit lines (GBLₓ) are elongated in the y-direction and each GBLₓ is disposed in different positions in the x-direction that are indicated by the subscript. Each of the global bit lines (GBLₓ) is selectively coupled to a respective selecting devices Q_{xy}, where a selecting device Q_{xy} shares the same position in the x-direction as the respective global bit line (GBLₓ) that it couples. As illustrated in FIG. 2, multiple selecting devices Q_{xy} are coupled to a respective global bit line (GBLₓ) along the y-direction.

Each of the selecting devices Q_{xy} selectively couples a respective local bit line (LBL_{xy}). The local bit line (LBL_{xy}) are elongated vertically, in the z-direction, and form a regular two-dimensional array in the x (row) and y (column) directions. For purposes of this discussion, a set of local bit lines (LBL_{xy})—e.g., the set 208 of LBLₓ₃ is defined as a group of local bit lines (LBL_{xy}) coupling respective global bit lines (GBLₓ) in the x-direction.

Each of the sets of LBL_{xy} is selectively coupled to a respective control or select gate lines (SG_{y}). For example, the set 208 of LBLₓ₃ is coupled to the select gate line SG₃. Each of the select gate lines (SG_{y}) is elongated in the x-direction and selectively couples a corresponding set of local bit lines (LBL_{xy}) to the global bit line (GBLₓ).

In various embodiments, during reading or programming, only one select device Q_{xy} is turned on at a time. Accordingly, during a reading or programming, one row or local bit lines (LBL_{xy}) of a set of LBL_{xy} is coupled to a global bit line (GBLₓ). During an example read or program operation, the select device Q₁₃ receives a voltage that makes the select device Q₁₃ conductive. The other select devices Q₂₃ and Q₃₃ receive voltages such that the select device Q₂₃ and Q₃₃ remain non-conductive. Thus, in this example, the global bit line (GBL₁) couples the local bit line (LBL₁₃) by way of the select device Q₁₃. In some embodiments, as one select device (Q_{xy}) is used with each of the local bit line (LBL_{xy}), the pitch of the array across the semiconductor substrate in both x and y-directions is made very small, and thus the density of the memory storage elements is increased.

Still referring to FIG. 2, the memory storage elements M_{zxy} are formed in a plurality of planes positioned at different distances in the z-direction above the substrate 204. For purposes of this discussion, two planes 206a and 206b are illustrated in the portion of memory 110. Plane 206a is disposed along the x-y plane having a value in the z-direction of 1. Plane 206b is similarly disposed along the x-y plane having a value in the z-direction of 2.

In each of the planes 206, word-line WL_{zy} are elongated in the x-direction and spaced apart in the y-direction between the local bit lines (LBL_{xy}). Individual word-lines WL_{zy} may physically be made up of one continuous material that is coupled to several different memory elements M_{zxy}. And individual memory elements M_{zxy} are accessed by way of one local bit line (LBL_{xy}) and a word-line (WL_{zy}). As used herein, memory elements may also be referred to as memory cells or cells. A memory element M_{zxy} is addressable by placing proper voltages on the local bit line (LBL_{xy}) and word-line (WL_{zy}) that couples the memory element M_{zxy}. During a program operation, voltages are applied that provide an appropriate amount of electrical stimulus that causes the state of the memory element to change to a desired value.

In various embodiments, each plane 206 is formed of at least two layers, one is a conductive layer that defines a word-line (WL_{zy}), and the second is a dielectric layer that electrically isolates the planes 206 from each other. The combined two layers is referred to as a word-line pitch. Additional layers may be present in each plane.

The planes 206 are stacked vertically on top of the substrate 204 layer, where each of the local bit lines (LBL_{xy}) extends perpendicular to each of the planes 206 to connect respective memory elements M_{zxy} in each of the planes 206.

FIG. 2b illustrates a top plan view 250 of each of the planes 206 of the portion of the memory 110. In the top plan view 250, the planes 206a and 206b are illustrated separately in order to show various aspects of an individual plane more clearly. In the plan view 250, for a given plane, the word-lines WL_{zy} extend vertically across each plane, while a representative cross section of the local bit lines LBL_{xy} is illustrated by blocks.

Each of the local bit lines LBL_{xy} would extend out toward the reader or extend perpendicular through the page. In the plan view, the direction that global bit lines GBLₓ are disposed in the substrate layer 204 are illustrated as horizontal across the page. Additionally, a direction that select gate lines SG_{y} are disposed in the substrate layer 204 is vertical—that is the select gate lines SG_{y} are parallel to the word-lines WL_{zy} when viewed from the top plan view.

In various embodiments, a memory block is defined by a group of memory elements M_{zxy}. In one example, a block of memory is the smallest unit of memory elements M_{zxy} that can be erased together. In one example, a memory block includes the memory elements M_{zxy} coupled on either side of one word-line, or a portion of a word-line in scenarios where word-lines are segmented. In FIG. 2b, an example memory block 252 includes the memory elements M_{zxy} coupled on either side, to the word-line and includes the memory elements M₁₃₂, M₁₂₂, M₁₁₂, M₁₃₃, M₁₂₃, and M₁₁₃.

Additionally, in some embodiments, a memory page is defined as the memory elements M_{zxy} along one side of a word-line. In FIG. 2b, an example memory page 254 is defined as the memory elements along one side of the word-line WL₁₁, and includes the memory elements M₁₃₃, M₁₂₃, and M₁₁₃.

FIG. 3 illustrates, in block diagram form, a perspective view of a memory 110, in an example three-dimensional (3-D) configuration. The 3-D memory 300 includes a set of blocks disposed on a substrate 302. For example, blocks BLK0, BLK1, BLK2, and BLK3 of memory cells are disposed on substrate 302. Peripheral areas 304 and 306 are also disposed within the substrate 302. The peripheral area 304 runs along an edge of each block while the peripheral area 302 is at the end of the set of blocks.

The peripheral areas 304 and 306 can include circuits used by the blocks. In some examples, the circuits include voltage drivers connected to control gate layers, bit lines and sources lines coupled to the blocks. The substrate 302 also includes circuits that are located under the blocks, along with one or more lower metal layers patterned in conductive paths to carry signals from the circuits. The blocks are formed in an intermediate region 308 of the memory 300, and an upper region 310 defines one or more metal layers patterned in conductive paths to carry signals of various circuits.

Each block includes a stacked area of memory cells, where alternative levels of the stack represent word lines. While four blocks are illustrated in FIG. 3, two or more blocks are used in various embodiments.

In various embodiments, during a read/program operation, interference from a neighboring word-line can impact how much a memory element is programmed or the amount of voltage, or time needed for programming a memory element to an appropriate value. For example, if one memory element is programmed first and a neighboring memory element (or second memory element) is programmed later, the program-level of the first memory element is influenced by the program amount of the second memory element. The second memory element influencing the first memory element is one example of neighbor or neighboring word-line interference (NWI).

When NWI occurs during programming, it increases errors during a read operation. For example, let's assume that the first memory element is programmed to a certain program-level/certain state (such as “A” state), initially. Later, when a neighboring memory element is programmed, if the program-level of the first memory element shifts up, it potentially moves to a different state (such as “B” state). This shift causes a read error when data from the first memory element is accessed.

In general, the amount of program-level shift of the first memory element is proportional to the program amount of the second memory element. In cases where the second memory element is deeply erased and programmed to a certain program-level, the first memory element will experience a greater program-level shift than cases where the second memory element is programmed from a normally erased state.

Additionally, a state of the neighboring word-line can impact data retention in the memory 110. For example, if two neighboring memory elements are in different states, there is a lateral electric field between the two memory elements, and carriers (electrons and/or holes) stored in the memory elements will diffuse along or against the electric field. This carrier diffusion results in charge loss or charge gain.

Charge loss in a programmed cell causes data retention problems. Furthermore, charge loss is worse if a neighboring memory element is in a deeply erased state. That is, if one memory element is programmed to a high state and a neighboring memory element is deeply erased, lateral diffusion of carriers increases due to the larger lateral electric field between the two memory elements. Thus greater charge loss occurs in the programmed cell which degrades data retention.

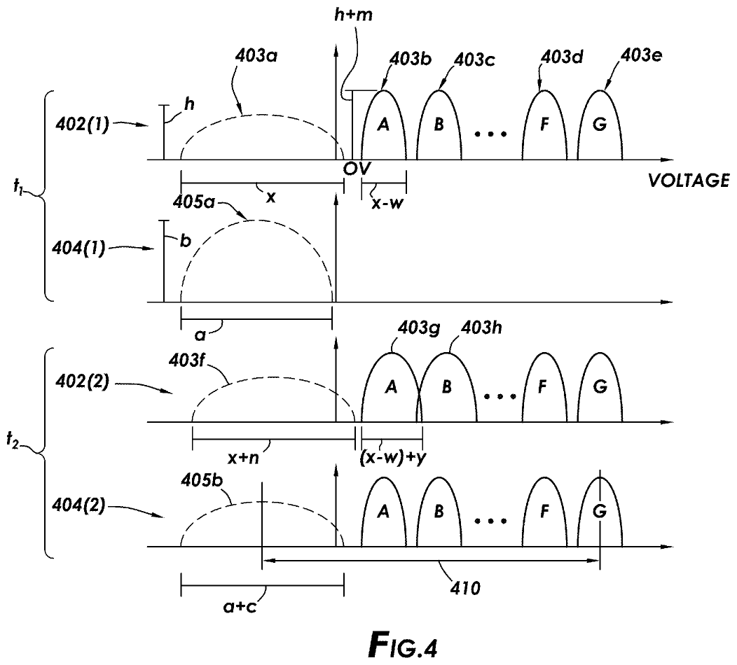

FIG. 4 illustrates plots demonstrating one phenomenon related to the impact of neighboring word-line interference during erase/program operations. Each of the plots 402(1)/(2) (“402”) and 404 (1)/(2) (“404”) illustrates a voltage distribution of memory elements in erased and programmed states. Voltage values are represented along the x-axis of each of the plots 402 and 404 while a quantity of memory elements is represented along the y-axis of each of the plots.

The plots 402 and 404 illustrate a snapshot of voltage distributions of memory elements during a first time (t1) and a second time (t2). Furthermore, the plots 402(1)/402(2) capture a distribution of voltages with respect to a memory block coupled to the word-line WLn—e.g., WL₁₁. The plots 404(1)/404(2) capture a distribution of voltages with respect to a memory block coupled to the word-line WLn+1—e.g., WL₁₂.

In particular, during the example first time (t1) a word-line WLn—e.g., WL₁₁—is programmed. During the example second time (t2), a neighboring word-line WLn+1—e.g., WL₁₂—is programmed. Thus, during the example first time (t1), the plots 402(1) and 404(1) capture a distribution of voltages in respective memory blocks after data is programmed in memory elements coupled to a word-line WLn—e.g., WL₁₁.

In one example, prior to time t(1), the example memory 110 may be in a state where all memory elements are erased. After memory elements coupled to the word-line WLn are programmed, respective distributions 403 are illustrated in the plot 402(1). In the plot 402(1), distribution 403a is associated with memory elements placed in an erased state, distributions 403b, 403c, 403d, and 403e are associated with memory elements placed in a programmed state.

The distribution 403a (erased memory elements) is a normal distribution curve having a dome-shape where a majority of the dome-shape is disposed along the negative x-axis—a majority of the memory elements that are in an erased state have a negative voltage. The distribution 403a has a width x and a height h.

Other memory elements coupled to the word-line WLn may be programmed to states including states A, B, F, and G. Accordingly, the voltage distributions of memory elements programmed to respective states is illustrated by the distributions 403b, 403c, 403d, and 403e. The example distribution 403b is associated with the memory elements programmed to a state “A” and represents a normal distribution curve.

The normal distribution curve has a width x-w and a height h+m. The width of a state can be defined by the standard deviation (or sigma) of the normal distribution. As an example, the x-axis distance between +3 sigma and −3 sigma can be defined as a 6 sigma width of the distribution. In this example, 99.7% of the memory elements in one state are in the 6-sigma width. The 6-sigma width is practically considered to be the width of a state.

Of note, the width x-w of the distribution 403b (programmed to state “A”) is smaller than a width of the distribution 403a (erased memory elements). Additionally, a height of the memory elements programmed to state “A” is higher (h+m) than a height of the erased memory elements (h).

Still referring to time t1 which occurs after the memory elements coupled to the word-line WLn are programmed—plot 404(1) illustrates a state of memory elements coupled to a neighboring word-line WLn+1—e.g., WL₁₂. As the block of memory elements coupled to the word-line WLn+1 have not been programmed, they remain erased.

The plot 404(1) illustrates a distribution 405a of the memory elements in an erased state. The distribution 405a has a width a and a height b. In some embodiments, the width a is larger than the width of the distribution associated with a programmed stated—e.g., width x-w associated with the programmed state “A”. Furthermore, the height b is less than a height of the distribution associated with a programmed state—e.g., height h+m associated with the programmed state “A”.

During the example second time (t2), the plots 402(2) and 404(2) capture a distribution of voltages in respective memory blocks after data is programmed in memory elements coupled to a word-line WLn+1—e.g., WL₁₂. As illustrated in the plot 402(2), after programming the memory elements coupled to the word-line WLn+1, the memory elements coupled to the word-line WLn+1 have voltage distributions similar to those after programming the memory elements coupled to the word-line WLn (plot 402(1)).

Specifically at the second time (t2), the distribution 405b (erased memory elements) defines a normal distribution curve having a dome shape where a majority of the dome-shape is disposed along the negative x-axis. The distribution 405b has a width a+c that is slightly wider than the width a of the distribution 405a.

For example, prior to programming the memory elements coupled to the word-line WLn+1, the distribution 405a of the erased memory elements coupled to word-line WLn+1 falls entirely along the negative x-axis. After programming the memory elements coupled to the word-line WLn+1, the distribution 405b widens such that a portion falls along some x values that are above zero. That is, after programming, the distribution of erased memory elements increases.

Furthermore, programming the memory elements coupled to the word-line WLn+1 has an impact on the distributions of the memory elements coupled to the neighboring word-line WLn. For example, as shown in the plot 402(2), various distributions become wider—where the distributions are associated with the memory elements coupled to the word-line WLn. That is, after a program operation, the distribution of the programmed and erased memory elements coupled to a neighboring word-line increases.

For example, at the second time (t2), the plot 402(2) illustrates the distribution 403f of the erased memory elements associated with the word-line WLn. The distribution 403f remain a normal distribution curve having a dome shape, however the dome shape is slightly wider. For example the distribution 403f has a width x+n, which is larger than the width of the erased memory elements prior to time (t2)—e.g., width x, plot 402(1), distribution 403a.

Additionally, at time (t2), the distribution of the memory elements coupled to the word-line WLn, that were previously programmed to states A, B, F, and G, also become wider. In plot 402(2), the memory elements programmed to a state “A” are represented by the distribution 403g. The same distribution prior to time t2 is represented by distribution 403b in the plot 402(1). The distribution 403g has a width (x−w)+y, while the distribution 403b has a width x-w. Thus, after the memory elements coupled to the word-line WLn+1 are programmed, the memory elements coupled to the neighboring word-line WLn experience voltage distributions that become wider.

Furthermore, whereas prior to the time t(2), the distributions of programmed memory elements coupled to the word-line WLn did not overlap, at time t(2), the distributions of the programmed memory elements coupled to the word-line WLn overlap. Specifically, the distributions associated with lower states—e.g., states “A” and “B”—programmed in memory elements coupled to the word-line WLn, become wider after the memory elements coupled to the word-line WLn+1 are programmed.

In some examples, the amount that the distributions (associated with word-line WLn) are widened is proportional to the voltage swing 410 between an erased state and programmed states of the memory elements associated with word-line WLn+1. The above described phenomenon occur due to neighboring word-line interference. That is, as described above, the programming of a neighboring word-line—e.g., WLn+1—impacts the word-line WLn.

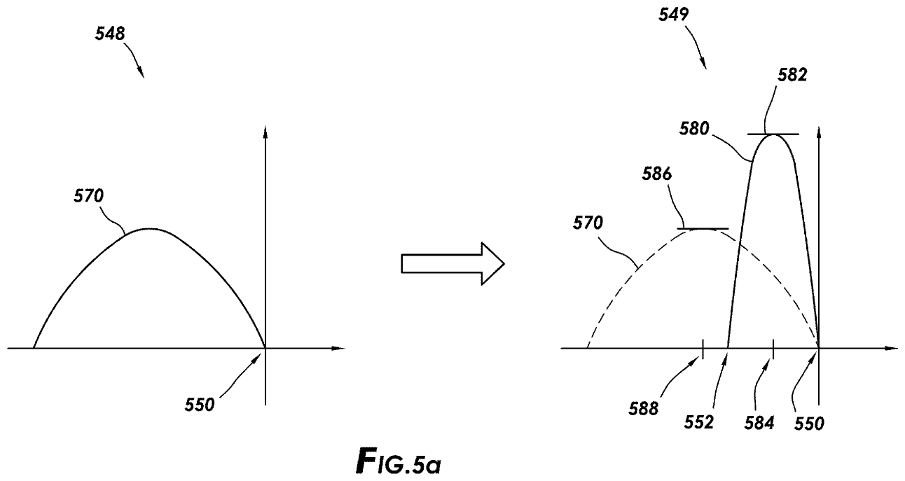

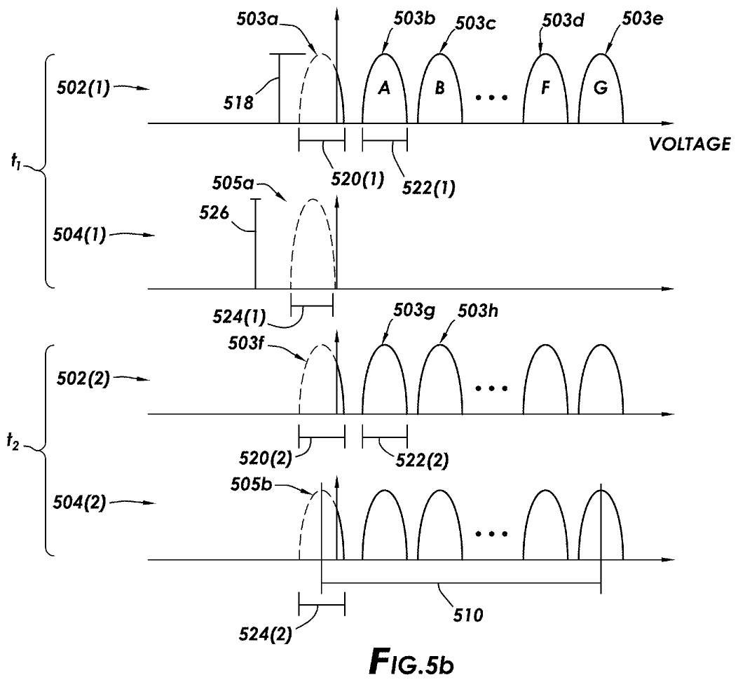

Embodiments described herein are directed to applying a compaction process to memory elements that are erased. To illustrate aspects of the compaction process, FIG. 5a illustrates plot 548 associated with memory elements that have been erased without undergoing a compaction process (e.g., conventional erase) and plot 549 in which the memory elements have been erased including the compaction process (e.g., using an erase program operation).

As used herein, the compacting process refers to a process that tightens the distribution of a particular state, such that the width of the distribution is smaller than before undergoing the compaction process. For example, the curve 570 illustrates a distribution of memory elements that have been erased without undergoing a compaction process. The curve 570 represents an example distribution curve resulting from a conventional erase operation. The curve 580 illustrates a distribution of memory elements that have been erased using an erase program operation which incorporates a compaction process.

In some embodiments, the compaction process results in increasing a height (582) or shifting a median value of the distribution (584) than a distribution of the particular state that has not undergone the compaction process (e.g., compare to height 586 and median value 588). In various embodiments, a majority of the distribution (6-sigma width) of the curve 580 falls within a threshold window defined between an erase verify level 550 and a compact erase threshold amount (or level) 552.

FIG. 5b illustrates plots demonstrating a scenario similar to that discussed in FIG. 4. In FIG. 5b, each of the plots 502 (1)/(2) (“502”) and 504 (1)/(2) (“504”) illustrates a voltage distribution of memory elements in erased and programmed states. Voltage values are represented along the x-axis of each of the plots 502 and 504 while a quantity of memory elements is represented along the y-axis of each of the plots.

In FIG. 5b, the memory elements coupled to the word-line WLn are programmed and then the memory elements coupled to the neighboring word-line WLn+1 are programmed. However, in FIG. 5b, memory elements are erased using the erase program operation which includes a compaction process as described herein.

For example, the distribution 503a has undergone a compaction process prior to the programming of the memory elements coupled to the word-line WLn. Thus, the distribution 503a has a width 520(1) that is smaller than the width x (plot 402(1)). The distribution 503a defines a height 518. And in some embodiments, the height 518 is larger than the height h (FIG. 4, plot 402(1)). In other embodiments, the height 518 is around the same as the height h+m (FIG. 4, plot 402(1)). The resulting dimensions of a distribution curve after undergoing a compaction process can vary based on the particular method used to implement the compaction process.

In one example, in order to apply a compaction process to the erased memory elements, a program operation—referred to herein as erase program operation—is applied. The erase program operation includes programming pulses with verify steps implemented between the programming pulses. In such an example, the erase program operation is applied such that deeply erased memory elements are “programmed” to a higher level in the erase state. In one example, the erase program operation is implemented by modifying all “A” state programming conditions which includes changing program-verify levels of the “A” state. In another example, the erase program operation is implement by modifying the “A” state programming conditions such that a median threshold voltage value of an erased block of cells after undergoing compaction is around −0.75 V from the much lower initial value (for example less than −2V).

Furthermore, similar to when memory elements are programmed to a programmed state, the erase program operation is complete when all memory elements have been programmed to an erase threshold amount referred to herein in the alternative as a compact erase threshold amount. The erase threshold amount/compact erase threshold amount defines a voltage value at which a memory element is considered to be in a “compact-erased” state.

After a conventional erase (i.e., a block that is erased without undergoing a compaction process), all memory elements in a block are below an erase verify level. Memory elements with slow erase speeds are erased to just below the erase verify level and memory elements with fast erase speeds are erased to much lower (or deeper) than the erase verify level. The memory elements with fast erase speeds and which are erased to a level much lower than the erase verify level are considered deeply erased memory elements. With the erase program operation described herein, these deeply erased memory elements are programmed to, or above, the compact erase threshold amount. Thus, after an erase program operation is complete, all memory elements are above the compact erase threshold amount but below the erase verify level.

In particular, the erase program operation is not an operation that is considered complete simply after one or a few program pulses are applied to all memory elements and irrespective of whether all the memory elements are considered to be in a compact-erased state. The erase program operation implements a verify step after program pulses and continues until all memory elements in the erased state have a more compact (or tightened) distribution. In other words, the erase program operation is considered complete after all memory elements have been “programmed” to the appropriate erase level (e.g., defined by the compact erase threshold amount).

The plots 502 and 504 illustrate a snapshot of voltage distributions of memory elements during a first time (t1) and a second time (t2). In particular, during the example first time (t1) a word-line WLn—e.g., WL₁₁—is programmed. During the example second time (t2), a neighboring word-line WLn+1—e.g., WL₁₂—is programmed.

During the example first time (t1), the plots 502(1) and 504(1) capture a distribution of voltages in respective memory blocks after data is programmed in memory elements coupled to a word-line WLn—e.g., WL₁₁. In particular, the plot 502(1) illustrates distributions associated with one block of memory—e.g., coupled to a word-line WLn, while plot 504(1) illustrates distributions associated with another block of memory—e.g., coupled to a neighboring word-line WLn+1.

Similar to the example described in FIG. 4, prior to the times t1 and t2, the example memory 110 may be in a state where all memory elements are erased. In contrast to the distributions of erased memory elements described in FIG. 4, the distribution of erased memory elements in FIG. 5b is tightened (also referred to herein as “compacted”). Accordingly, in the plots 502 and 504, prior to the time t1, the erased memory elements have undergone the compaction process. And in one example, the compaction process is implemented using the erase program operation.

In plot 502(1), distribution 503a is associated with memory elements placed in an erased state. In plot 502(1), the distributions 503b, 503 c, 503d, and 503e are associated with memory elements placed in a programmed state.

The distribution 503a (erased memory elements) is a normal distribution curve where a majority of the memory elements is disposed along the negative x-axis—a majority of the memory elements that are in an erased state have a negative voltage. The distribution 503a has a width 520(1). As the distribution 503a has been compacted, the width 520(1) of the distribution 503a is smaller than the width x of the distribution of erased memory elements without compaction (FIG. 4, plot 402(1)).

Other memory elements coupled to the word-line WLn may be programmed to states including states A, B, F, and G. The voltage distributions of memory elements programmed to respective states is illustrated by the distributions 503b, 503c, 503d, and 503e. The example distribution 503b is associated with the memory elements programmed to state “A” and represents a normal distribution curve. The normal distribution curve has a width 522(1). In some embodiments, as the erase program operation is implemented in a manner similar to a program operation, the dimensions of the normal distribution curve for state “A” is similar to the normal distribution curve for the erase state.

Still referring to FIG. 5b, at time t(1) which occurs after the memory elements coupled to the word-line WLn are programmed—plot 504(1) illustrates a state of memory elements coupled to a neighboring word-line WLn+1—e.g., WL₁₂. As the blocks of memory elements coupled to the word-line WLn+1 have not been programmed, they remain erased.

The plot 504(1) illustrates a distribution 505a of the memory elements in a compact-erased state. The distribution 505a has a width 524 and a height 526. The distribution 505a represents a distribution of erased memory elements in a block prior to the block being programmed. Furthermore, the distribution 505a represents erased memory elements where the distribution has been compacted.

In some embodiments, the width 524 of the distribution 505a is the same as or smaller than a width associated with a distribution of programmed memory elements (e.g., 522(1)). In other embodiments, the height 526 is larger than a height associated with a distribution of programmed memory elements.

During the example second time (t2), the plots 502(2) and 504(2) capture a distribution of voltages in respective memory blocks after data is programmed in memory elements coupled to a word-line WLn+1—e.g., WL₁₂. As illustrated in the plot 502(2), after programming the memory elements coupled to the word-line WLn+1, the memory elements coupled to the word-line WLn+1 have voltage distributions similar to those after programming the memory elements coupled to the word-line WLn (plot 502(1)).

Specifically, at the second time (t2), the distribution 505b (erased memory elements) defines a normal distribution curve where a majority of the normal distribution is disposed along the negative x-axis. The distribution 505b has a width 524(2) that is slightly wider than the width 524(1). That is, similar to the scenario in FIG. 4, after programming, the distribution of erased memory elements increases.

For example, prior to programming the memory elements coupled to the word-line WLn+1, the distribution 505a of the erased memory elements coupled to word-line WLn+1 falls entirely along x-values less than zero. After programming the memory elements coupled to the word-line WLn+1, the distribution 505b widens such that a portion of the distribution 505b includes some x values that are above zero.

Similar to the scenario in FIG. 4, programming the memory elements coupled to the word-line WLn+1 has an impact on the distributions of the memory elements coupled to the neighboring word-line WLn. For example, as shown in the plot 502(2), various distribution become wider. However, due to the compaction of erased memory elements, the impact is less.

For example, in FIG. 5b, at the second time (t2), the plot 502(2) illustrates the distribution 503f of the erased memory elements associated with the word-line WLn. The distribution 503f remains a normal distribution curve having a width 520(2) slightly larger than the width of the erased memory elements prior to time (t2)—e.g., width 520(1), plot 502(1).

Additionally, at time (t2), the distribution of the memory elements coupled to the word-line WLn that were previously programmed to states A, B, F, And G, also become wider. In plot 502(2), the memory elements programmed to a state “A” are represented by the distribution 503g, The same distribution prior to time t2 is represented by distribution 503b in the plot 502(1). The distribution 503g has a width 522(2), while the distribution 503b has a width 522(1), where the width 522(2) is slightly larger than the width 522(1). Thus, similar to FIG. 4, the programming of a neighboring word-line—e.g., WLn+1—impacts the word-line WLn.

However, in contrast to the scenario described in FIG. 4, because the distribution of the erased memory elements were compacted, the impact on the word-line WLn is reduced. For example, unlike the scenario described in FIG. 4, after the word-line WLn+1 is programmed, the distribution of the programmed memory elements coupled to the word-line WLn do not overlap. The distributions associated with lower-states—e.g., states “A” and “B”—programmed in memory elements coupled to the word-line WLn become wider after the memory elements coupled to the word-line WLn+1 are programmed. However, because the distribution of erased memory elements were previously compacted, the distributions do not become so wide as to overlap—as was the case in FIG. 4.

As explained in FIG. 4, the amount that the distributions (associated with word-line WLn) are widened is proportional to the voltage swing 510 between an erased state (or compact-erased state) and programmed states of the memory elements associated with word-line WLn+1. As the memory elements in the compact-erased state were previously compacted, the voltage swing 510 is less than the voltage swing 410 (FIG. 4).

Of note, the compacting process not only reduces a width of the distribution of erased memory elements, the compacting process may also move a median value of the erased memory elements closer to the zero x-value (see difference in median values 584 and 588 in FIG. 5a). Thus, the spread of deeply erased memory elements is reduced. As a number of deeply erased memory elements is reduced by the compacting process, an amount of lateral charge loss is reduced that might otherwise occur when programming memory elements coupled to a word-line that is adjacent deeply erased memory elements. As the compacting process helps reduce the impacts on a word-line of programming a neighboring word-line, the compacting process helps increase data retention. That is, by reducing a number of over-erased cells in a block of memory elements by applying the compacting process, a controller increases data retention.

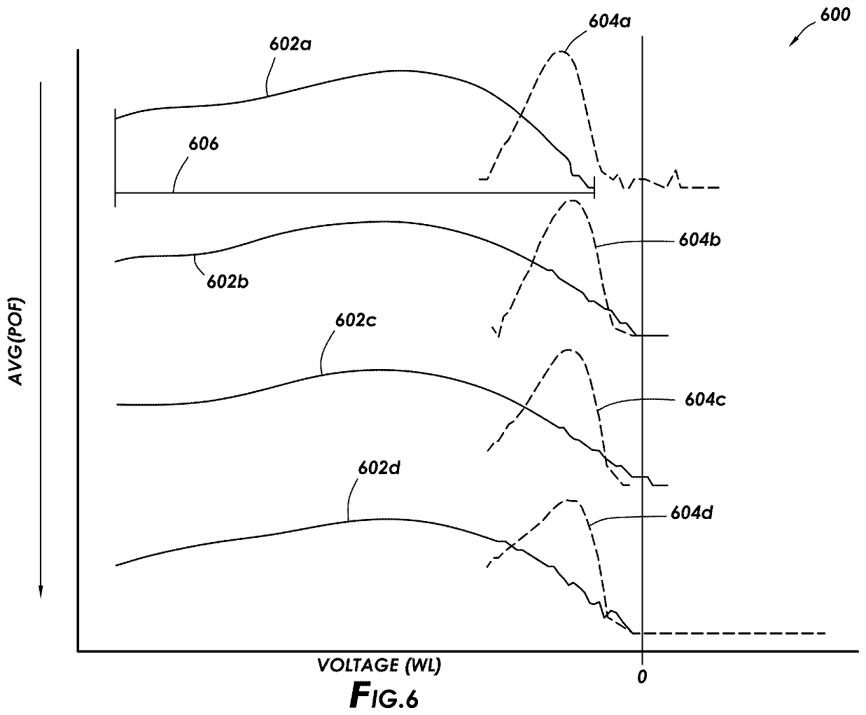

FIG. 6, illustrates various example normal distribution curves that may result from applying the compaction process to various flash technologies. The plot 600 illustrates technologies ranging from 50 nanometers to 44 nanometers. In one example, distribution curves 602a and 604a are associated with 50 nanometer technology, distribution curves 602b and 604b are associated with 48 nanometer technology, distribution curves 602c and 604c are associated with 46 nanometer technology, and distribution curves 602d and 604d are associated with 44 nanometer technology.

The distribution curves 602a, 602b, 602c, and 602d illustrate respective distributions of erased memory elements, where the distribution has not undergone a compaction process. Each of the curves 602 demonstrates a distribution with a fairly large width—e.g., width 606 of distribution 602. A median range of the distributions 602 is several units away in the negative direction from the voltage value zero.

FIG. 6 also illustrates the distribution curves 604a, 604b, 604c, and 604d. The distribution curves 604 represent estimations. The distribution curves 604 illustrate respective distributions of erased memory elements, where the distribution has undergone a compaction process. As illustrated, after a distribution undergoes a compaction process: 1) a width of the distribution is reduced, 2) a height of the distribution is increased, and 3) a median value of the distribution is shifted closer to the voltage value zero.

In FIG. 6, the estimation of the distribution curves 604 reflects a method of implementing the compaction process using an erase program operation. In the example, the program operation to program a memory element to a program state “A” was modified to create an erase program operation. In one example, because the “A” state is the first program state above an erase state, the original verify level of “A” state programming is at least several hundred millivolts higher than the erase verify level. The voltage of “A” state programming is large enough to program the memory elements from erase state to “A” state without applying too many program pulses.

In order to create an example erase program operation, a modification of the program operation for the state “A” includes lowering the “A” state verify level to a the compact erase threshold amount (or level). Additional modification include a weaker starting programming pulse and smaller increments of the program pulse. In particular, the weaker starting programming pulse is implemented to realize the lower verify level, while the smaller increments of the program pulse is implemented to realize a narrow (compact) distribution.

For sake of example, let's assume that the original “A” state verify level is 0.5V above the erase verify level and a target width of a erase distribution after compaction (e.g., associated with an erase program operation/compact-erased state) is around 1V. Accordingly, the compact erase threshold amount (of level) should be 1V lower than the erase verify level. Therefore, “A” state verify level is lowered by 1.5V from its original verify level to create a compact erase threshold amount or compact erase verify level.

In various embodiments a verify level is lowered either by directly lowering the verify level parameter or by combining with other parameters that affect the verify level. Program verify is a process of comparing the current through the memory element (or cell current) with a reference current level (or sensing level). If the cell current is smaller than the sensing level, the memory element is considered to pass the program verify.

By modifying the conditions for measuring cell current or a sensing level, a controller changes the verify level even if a memory elements have been programmed to the same level (i.e., the same number of electrons stored in the memory element). As an example, to achieve a verify level that is 1.5V lower, the “A” state verify level is decreased by 775 mV. Additionally, the drain voltage during verify (VBLC PVFY) is decreased by 150 mV and the source voltage (CELSRC) is increased by 450 mV to reduce the cell current. In some embodiments, these modifications have the effect of lowering a verify level by approximately 600 mV.

Furthermore, increasing a sensing level increases the difference between sensing level and the cell current, which makes verify easy—or has an effect similar to lowering the verify level. Thus, in this example, the combined modification can have an impact of lowering a verify level by 1.5V. A weaker programming pulse is achieved by lowering a starting programming voltage (VPGMU) by 1V and implementing a smaller step-size (e.g., 50 mV DVPGMU). Thus, a distribution that undergoes a compaction process (e.g., associated with an erase program operation/compact-erased state) becomes approximately 1V.

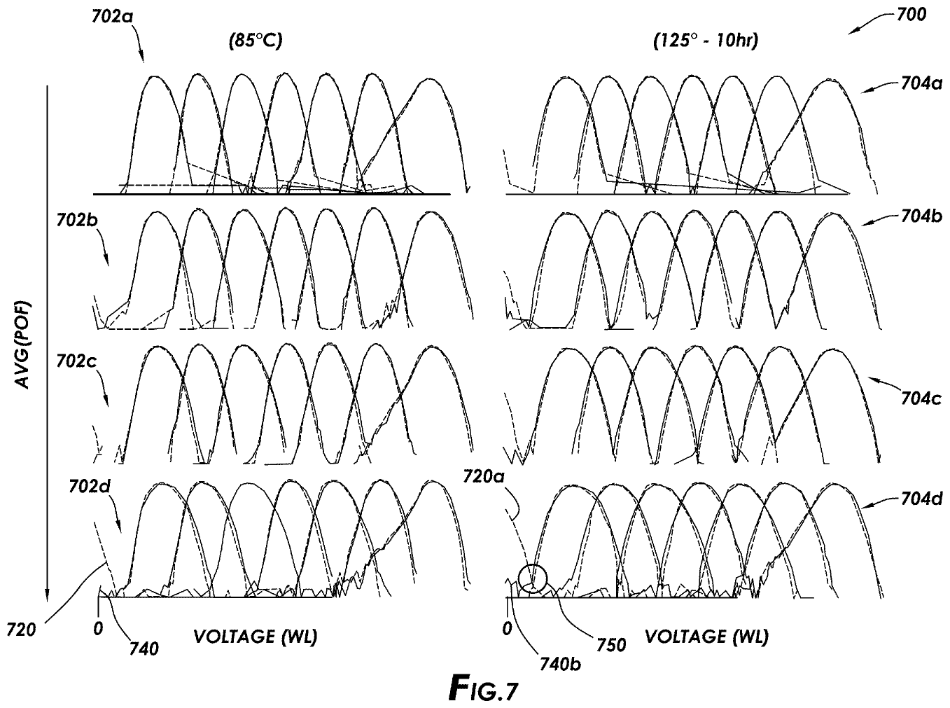

FIG. 7 illustrates the effects of applying the compaction process to erased cells in the context of a high temperature data retention simulation. The plot 700 illustrates technologies ranging from 50 nanometers to 44 nanometers. In one example, the distribution plots 702a and 704a are associated with 50 nanometer technology, the distribution plots 702b and 704b are associated with 48 nanometer technology, the distribution plots 702c and 704c are associated with 46 nanometer technology, and the distribution plots 702d and 704d are associated with 44 nanometer technology.

The distribution plots 702a, 702b, 702c, and 702d illustrate respective normal distribution curves of various programmed and erased states/compact-erased states at an initial temperature of 85 degrees Celsius. Each of the plots 702 demonstrates two curves. In the plots, curves illustrated with a dashed line are associated with a memory where erased memory elements underwent a compaction process—e.g., distribution 720. In the plots, curves illustrated with a solid line are associated with a memory where erased memory elements did not undergo a compaction process—e.g., distribution 740.

In the plot 700, the distribution plots 704a, 704b, 704c, and 704d illustrate respective normal distribution curves of various programmed and erased states/compact-erased states after undergoing a high temperate bake at 125 degrees Celsius for 10 hours. Each of the plots 704 corresponds to a respective plot 702. Accordingly, each of the plots 704 demonstrates two curves. One curve is associated with a memory where erased memory elements underwent a compaction process—e.g., distribution 720a. The other curve is associated with a memory where erased memory elements did not undergo a compaction process—e.g., distribution 740b.

Of note, based on the data observed in FIG. 7, it is estimated that applying the compaction process to erased cells will help reduce read errors at initial program and after data retention bake. Bigger overlaps between adjacent states in normal distribution indicate a higher probability of read errors. One metric for determining the overlap amount is the sum of the widths of programmed states except for the highest program state (e.g., “G” state). As described herein, a width is defined as a 6-sigma width—a difference between a +3 sigma and a −3 sigma of a normal distribution. That is, the sum of the 6-sigma widths of the distributions associated with states “A,” “B,” “C,” “D,” “E,” and “F,” (referred to herein as “A-F 6-sigma width”) is one metric for predicting errors.

A wider A-F 6-sigma width may coincide when more overlap is present between two adjacent states—which indicates a higher probability of read errors. At initial program, A-F 6-sigma width for memory elements that have undergone the compaction process (e.g., erase program operation) is 130 mV-350 mV smaller than those associated with memory elements that have not undergone the compaction process (e.g., memory elements that have undergone a conventional block erase).

After data retention bake, the difference becomes even larger. The A-F 6-sigma width for memory elements that have undergone the compaction process (e.g., erase program operation) is 320 mV-700 mV smaller than those associated with memory elements that have not undergone the compaction process (e.g., memory elements that have undergone a conventional block erase).

As described herein, less overlap in the normal distributions associated with memory elements that have undergone the compaction process over a conventional erase case at initial program is due to smaller neighboring word-line interference (NWI). During data retention bake, when an erase program operation is performed (e.g., memory cells have undergone a compaction process), the fewer number of over-erased memory elements help decrease lateral electric field. The decreased lateral electric field results in less lateral charge loss and less overlap in adjacent program states. In this way, the probability of read errors will decrease through the lifetime of the memory elements, when the memory elements undergo the compaction process—for example as part of an erase program operation.

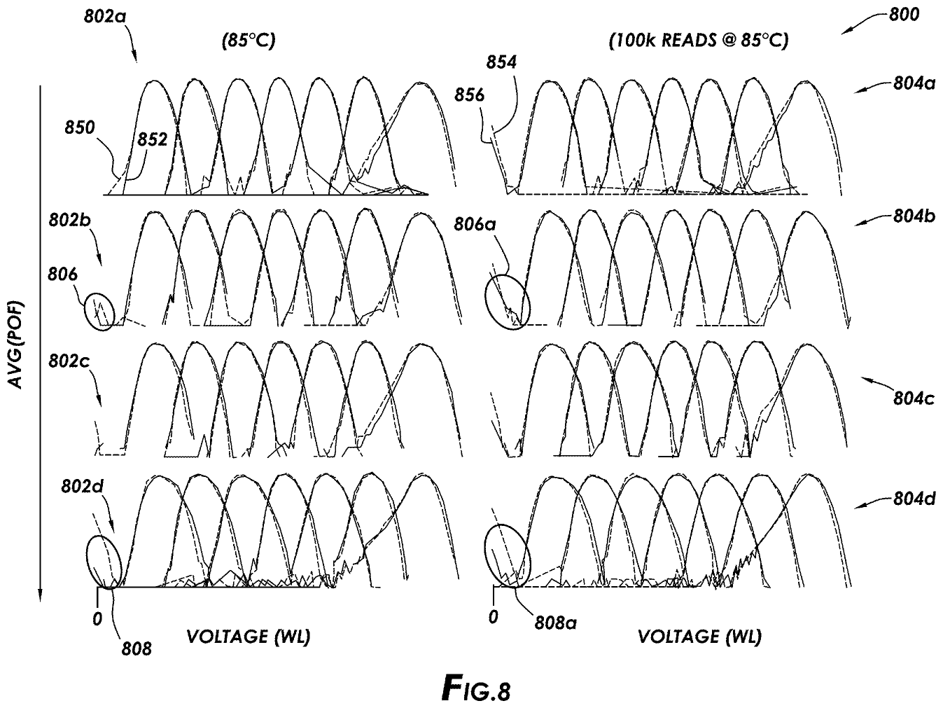

FIG. 8, illustrates the effects of applying the compaction process to erased cells in the context of a high number of reads. The plot 800 illustrates technologies ranging from 50 nanometers to 44 nanometers. In one example, the distribution plots 802a and 804a are associated with 50 nanometer technology, the distribution plots 802b and 804b are associated with 48 nanometer technology, the distribution plots 802c and 804c are associated with 46 nanometer technology, and the distribution plots 802d and 804d are associated with 44 nanometer technology.

The distribution plots 802a, 802b, 802c, and 802d illustrate respective normal distribution curves of various programmed and erased states/compact-erased states at a temperature of 80 degrees Celsius in a memory where zero read operations have been performed. Each of the plots 802 demonstrates two curves. In the plots, curves illustrated with a dashed line are associated with a memory where erased memory elements underwent a compaction process—e.g., distribution 850. In the plots, curves illustrated with a solid line are associated with a memory where erased memory elements did not undergo a compaction process—e.g., distribution 852.

In the plot 800, the distribution plots 804a, 804b, 804c, and 804d illustrate respective normal distribution curves of various programmed and erased states/compact-erased states after undergoing 100,000 read operations at 85 degrees Celsius. Each of the plots 804 correspond to a respective plot 802. Accordingly, each of the plots 804 demonstrates two curves. One curve is associated with a memory where erased memory elements underwent a compaction process—e.g., distribution 854. The other curve is associated with a memory where erased memory elements did not undergo a compaction process—e.g., distribution 856.

Of note, based on the data observed in FIG. 8, it is estimated that applying the compaction process to erased cells does not degrade read disturb. For example, after a large number of reads, the plots 802b and 804b illustrate that when a compaction process is applied to erased memory cells, the distribution largely retains a shape similar to a shape of the distribution prior to the large number of reads. In particular, the right side of the distribution does not overlap into a region of the programmed states—e.g., see locations 806, 806a, 808, and 808a.

Because the compaction process causes a population of a majority of the erase cells to fall near the erase verify level, after undergoing the compaction process, the upper tail of the compact-erased state may be closer to the lower tail of the “A” state. In contrast, erased cells that have not undergone the compaction process may be further from the lower tail of the “A” state. The distance between the upper tail of an compact-erased state and the “A” state lower tail will decrease further with repeated read operations. However, as described herein, the shift of the upper tail of the compact erased state is no worse than a shift of the upper tail of conventional erased state (no compaction process).

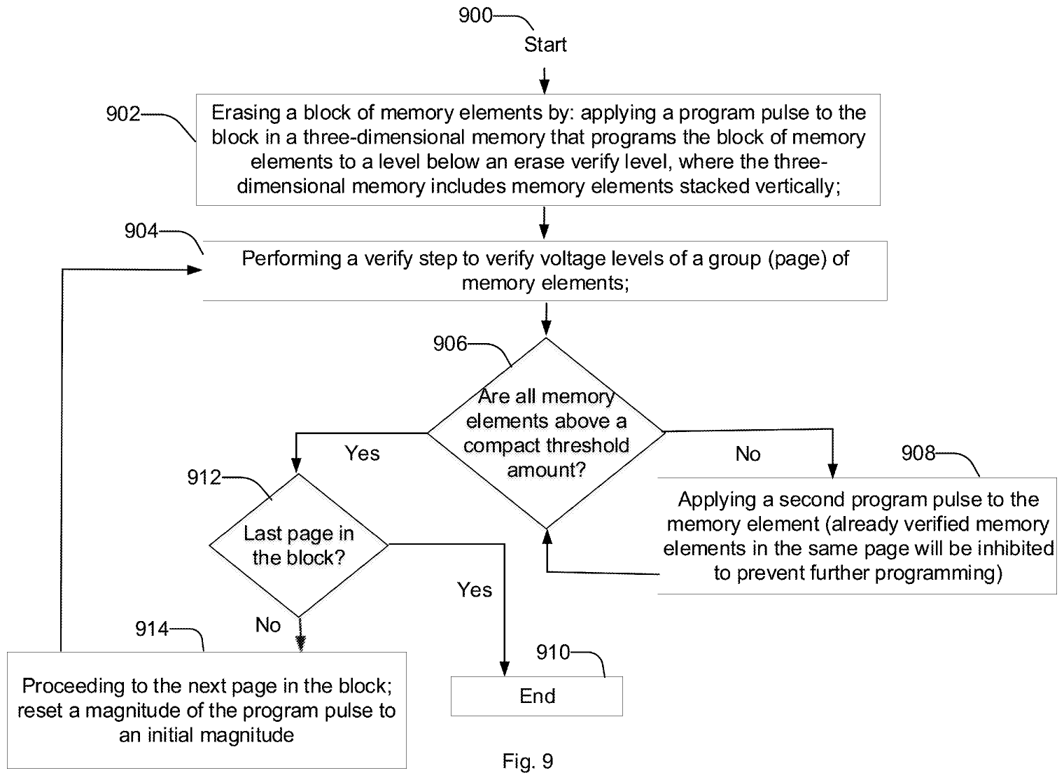

FIG. 9 shows a method in accordance with at least some embodiments. In particular, the method is performed at a memory system (e.g., the storage system 102) and includes erasing a block of memory elements—i.e., memory elements M_{zxy}—by: applying a program pulse to the block in a three-dimensional memory that programs the block of memory elements to a level below an erase verify level, where the three-dimensional memory includes memory elements stacked vertically (block 902). As described herein, the program pulse is part of an erase program operation that programs the memory elements to a compact-erased state. As further described herein, compacting the distribution of erased memory elements can reduce impacts caused by neighboring word-line interference.

Next, the memory system performs a verify step to verify voltage levels of a group (page) of memory elements (block 904). The memory system determines whether all memory elements are above a compact threshold amount (decision block 906). As described herein, a threshold window is defined between the erase verify level and the compact erase threshold amount. The erase program operation is considered complete when a six-sigma width of the normal distribution of the memory elements in the compact-erased state is within the threshold window.

Further, reference to all memory elements as used herein is satisfied when a six-sigma width of the distribution associated with the memory elements programed to the compact-erase state is within the threshold window. That is, when the six-sigma window is within the threshold window, all memory elements are considered to be above the compact threshold amount. Thus, the erase program operation includes determining whether all memory elements are above a compact threshold amount.

In the case where some memory elements are below the compact threshold amount, the memory system applies a second program pulse to a respective memory element (block 908). During the second program pulse, other memory elements within the page are inhibited from further programming. These other memory elements are already within the threshold window. Additionally, the pulse magnitude may be increased if the verify-program routine repeats past a threshold number of loops.

In the case where all memory elements are above a compact threshold amount, the memory system determines whether the page is the last page in the block (decision block 912). In the event the page is not the last page in the block, the memory system proceeds to the next page in the block (block 914). In some embodiments, upon starting at a new page, the memory system may reset a magnitude of the programming pulse (for the erase program operation) to an initial magnitude. In the event the page is the last page in the block, the method ends (block 910).

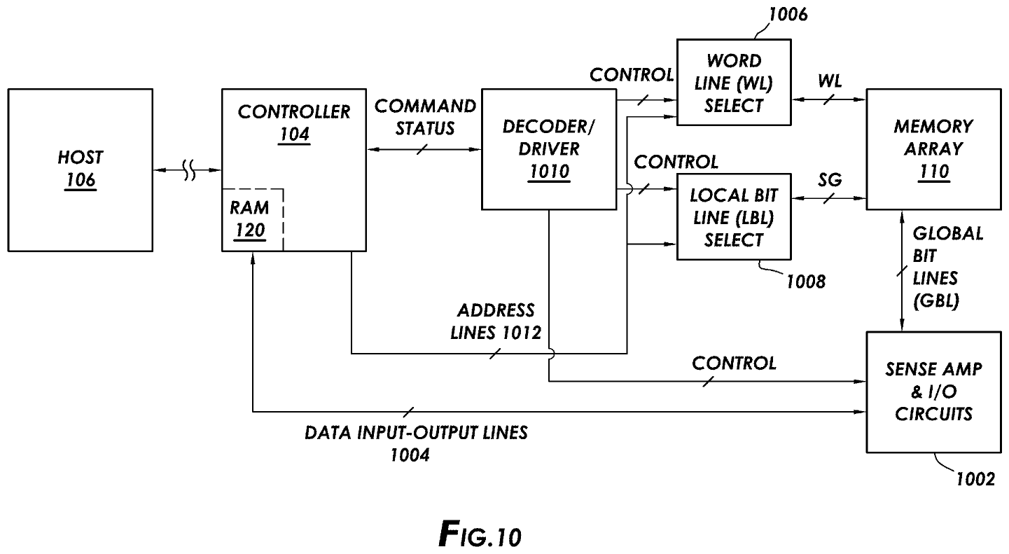

FIG. 10 shows in block diagram form, an illustrative memory system that can use the three-dimensional memory 110. Sense amplifier and I/O circuits 1002 are connected to provide (during programming) and receive (during reading) analog electrical quantities in parallel over the global bit-lines GBLₓ (FIG. 2a) that are representative of data stored in addressed memory elements M_{zxy}. The circuits 1002 contain sense amplifiers for converting these electrical quantities into digital data values during reading, which digital values are then conveyed over lines 1004 to the memory controller 104.

Conversely, data to be programmed into the memory 110 are sent by the controller 104 to the sense amplifier and I/O circuits 1002, which then programs that data into addressed memory elements by placing proper voltages on the global bit lines GBLₓ. The memory elements are addressed for reading or programming by voltages placed on the word-lines WL_{zy} and select gate control lines SG_{y} by respective word-line select circuits 1006 and local bit line circuits 1008.

In the memory 110, the memory elements lying between a selected word-line and any of the local bit lines LBL_{xy} connected at one instance through the select devices Q_{xy} to the global bit lines GBLₓ may be addressed for programming or reading by appropriate voltages being applied through the select circuits 1106 and 1008.

The controller 104 receives data from and sends data to the host 106. Commands, status signals and addresses of data being read or programmed are exchanged between the controller 104 and host 106.

The controller 104 conveys to decoder/driver circuits 1010 commands received from the host. Similarly, status signals generated by the memory system are communicated to the controller 104 from the circuits 1010. The circuit 1010 can be simple logic circuits in the case where the controller controls nearly all of the memory operations, or can include a state machine to control at least some of the repetitive memory operations necessary to carry out given commands. Control signals resulting from decoding commands are applied from the circuits 1010 to the word-line select circuits 1006, local bit line select circuits 1008, and sense amplifier and I/O circuits 1002.

Also connected to the circuits 1006 and 1008 are address lines 1012 from the controller that carry physical addresses of memory elements to be accessed within the array 110 in order to carry out a command from the host. The physical addresses correspond to logical addresses received from the host 106, where the physical addresses are converted to logical addresses by the controller 104 and/or the decoder/driver 1010.

As a result, the circuits 1008 partially address the designated storage elements within the array 110 by placing proper voltages on the control elements of the select devices Q_{xy} to connect selected local bit lines (LBL_{xy}) with the global bit lines (GBLₓ). The addressing is completed by the circuits 1006 applying proper voltages to the word-lines WL_{zy} of the array.

Although the memory system of FIG. 10 utilizes the three-dimensional memory 110 of FIG. 1, the system is not limited to use of only that array architecture. A given memory system may alternatively combine this type of memory with other types including flash memory, such as flash having a NAND memory cell array architecture, a magnetic disk drive, or some other type of memory. The other type of memory may have its own controller or may in some cases share the controller 104 with the three-dimensional memory 110, for example if there is some compatibility between the two types of memory at an operational level.

The above discussion is meant to be illustrative of the principles and various embodiments described herein. Numerous variations and modifications will become apparent to those skilled in the art once the above disclosure is fully appreciated. For example, although a controller 104 has been described as performing the methods described above, any processor executing software within a host system can perform the methods described above without departing from the scope of this disclosure. In particular, the methods and techniques described herein as performed in the controller, may also be performed in a host. Furthermore, the methods and concepts disclosed herein may be applied to other types of persistent memories other than flash. It is intended that the following claims be interpreted to embrace all such variations and modifications.

What is claimed is:

1. A method for reducing neighboring word-line interference in a three-dimensional memory, comprising:
erasing a block of memory elements by:
applying a program pulse to the block of memory elements in the three-dimensional memory that programs the block of memory elements to a level below an erase verify level, wherein the three-dimensional memory comprises memory elements stacked vertically;
performing a verify step to verify voltage levels of a group of memory elements;
determining that a memory element of the group of memory elements is outside a threshold window defined between the erase verify level and a compact erase threshold amount; and
applying a second program pulse to the memory element.

2. The method of claim 1, wherein the erasing the block of memory elements creates an erased block, wherein a width of a voltage distribution of the erased memory elements in the erased block is the same as or below a width of a voltage distribution associated with programmed memory elements.

3. The method of claim 1,
wherein the erasing the block of memory elements creates an erased block,
wherein a voltage distribution of the erased memory elements in the erased block is a first amount at a first time,
wherein a voltage distribution of erased memory elements in the erased block is a second amount after a bake time, and
wherein the second amount is the same as or below a threshold amount of a voltage distribution associated with programmed memory elements.

4. The method of claim 1,
wherein the erasing the block of memory elements creates an erased block,
wherein a voltage distribution of the erased memory elements in the erased block is a first amount at a first time,
wherein a voltage distribution of the erased memory elements in the erased block is a second amount after a number of reads above a read threshold, and
wherein the second amount is the same as or below a threshold amount of a voltage distribution associated with programmed memory elements.

5. The method of claim 1, wherein the erasing the block of memory elements is complete when a six-sigma width of the distribution of the memory elements in the block of memory elements is within the threshold window.

6. The method of claim 1,
wherein the erasing the block of memory elements creates an erased block with a compact-erased voltage distribution, and
wherein a median value of the compact-erased voltage distribution is higher than a median value of a voltage distribution associated with a group of memory elements erased with a conventional erase operation.

7. A memory controller, comprising:
a first terminal configured to couple to a three-dimensional memory, wherein the three-dimensional memory comprises memory elements stacked vertically,
the memory controller configured to use an erase program operation that erases the memory block to a compact-erased state, wherein when the controller applies the erase program operation, the controller is configured to:
apply a program pulse to a block of memory elements in the three-dimensional memory that programs the block of memory elements to a level below an erase verify level;
perform a verify step to verify voltage levels of a group of memory elements;
determine that a memory element of the group of memory elements is outside a threshold window defined between the erase verify level and a compact erase threshold amount; and
apply a second program pulse to the memory element.

8. The memory controller of claim 7, wherein when the controller applies the erase program operation, the controller creates an erased block, wherein a width of a voltage distribution of the erased memory elements in the erased block is the same as or below a width of a voltage distribution associated with programmed memory elements.

9. The memory controller of claim 7,
wherein when the controller applies the erase program operation, the controller creates an erased block,
wherein a voltage distribution of the erased memory elements in the erased block is a first amount at a first time,
wherein a voltage distribution of erased memory elements in the erased block is a second amount after a bake time, and
wherein the second amount is the same as or below a threshold amount of a voltage distribution associated with programmed memory elements.

10. The memory controller of claim 7,
wherein when the controller applies the erase program operation, the controller creates an erased block,
wherein a voltage distribution of the erased memory elements in the erased block is a first amount at a first time,
wherein a voltage distribution of the erased memory elements in the erased block is a second amount after a number of reads above a read threshold; and
wherein the second amount is the same as or below a threshold amount of a voltage distribution associated with programmed memory elements.

11. The memory controller of claim 7, wherein the erase program operation is complete when a six-sigma width of the distribution of the memory elements in the block of memory elements is within the threshold window.

12. The memory controller of claim 7,
wherein when the controller applies the erase program operation, the controller creates an erased block with a compact-erased voltage distribution, and
wherein a median value of the compact-erased voltage distribution is higher than a median value of a voltage distribution associated with a group of memory elements erased with a conventional erase operation.

13. A non-volatile storage system, configured to perform an erase program operation, comprising:
a three-dimensional memory comprising memory elements stacked vertically; and
a controller coupled to the three-dimensional memory, wherein the controller is configured to erase a block of memory elements by using the erase program operation, wherein when the controller applies the erase program operation, the controller is configured to:
apply a program pulse to the block of memory elements in the three-dimensional memory that programs the block of memory elements to a level below an erase verify level;
perform a verify step to verify voltage levels of a group of memory elements;
determine that a memory element of the group of memory elements is outside of a threshold window defined between the erase verify level and a compact erase threshold amount; and
apply a second program pulse to the memory element.

14. The non-volatile storage system of claim 13, wherein when the controller applies the erase program operation, the controller creates an erased block, wherein a width of a voltage distribution of the erased block is the same as or below a width of a voltage distribution associated with programmed memory elements.

15. The non-volatile storage system of claim 13,
wherein when the controller applies the erase program operation, the controller creates an erased block,
wherein a voltage distribution of the erased memory elements in the erased block is a first amount at a first time,
wherein a voltage distribution of erased memory elements in the erased block is a second amount after a bake time, and
wherein the second amount is the same as or below a threshold amount of a voltage distribution associated with programmed memory elements.

16. The non-volatile storage system of claim 13,
wherein when the controller applies the erase program operation, the controller creates an erased block,
wherein a voltage distribution of the erased memory elements in the erased block is a first amount at a first time,
wherein a voltage distribution of the erased memory elements in the erased block is a second amount after a number of reads above a read threshold, and
wherein the second amount is the same as or below a threshold amount of a voltage distribution associated with programmed memory elements.

17. The non-volatile storage system of claim 13, wherein the erase program operation is complete when a six-sigma width of the distribution of the memory elements in the block of memory elements is within the threshold window.

18. The non-volatile storage system of claim 13,
wherein when the controller applies the erase program operation, the controller creates an erased block with a compact-erased voltage distribution, and
wherein a median value of the compact-erased voltage distribution is higher than a median value of a voltage distribution associated with a group of memory elements erased with a conventional erase operation.

19. The non-volatile storage system of claim 13, wherein when the controller applies the erase program operation, the controller increases data retention by reducing a number of deeply erased memory elements in the block from a number of deeply erased memory elements created in response to a conventional erase operation.

20. The non-volatile storage system of claim 19, wherein when the controller applies the erase program operation, an amount of lateral charge loss occurring during a program operation is reduced from an amount of lateral charge loss occurring in the block of memory elements that are erased using a conventional erase operation.
